(19) United States
(12) Patent Application Publication
(10) Pub. No.: US 2004/0262601 A1
(43) Pub. Date: Dec. 30, 2004

(54) Organic field-effect transistor and method of manufacturing same

(76) Inventor: Hidenori Okuzaki, Yamanashi-Ken (JP)

Correspondence Address: DICKSTEIN SHAPIRO MORIN & OSHINSKY LLP, 2101 L STREET NW, WASHINGTON, DC, 20037-1526, US

(21) Appl. No.: 10/638,538

(22) Filed: Aug. 12, 2003

Related U.S. Application Data
(63) Continuation-in-part of application No. PCT/JP03/05750, filed on May 8, 2003.

(30) Foreign Application Priority Data
Aug. 22, 2002 (JP) 2002-242443
Jul. 17, 2003 (JP) 2003-198225

(51) Int. Cl. H01L 35/24

(52) U.S. Cl. 257/40

(57) ABSTRACT

An organic field-effect transistor having a simple structure and employing an organic conductor is such that at least a channel is formed by an organic conducting material. For example, the transistor includes a single organic insulating substrate on which an organic conducting layer is formed in such a manner that portions that act as a source, channel and drain are rendered continuous. An insulating layer is formed on the organic conducting layer, with the exception of at least part of the portions thereof that act as the source and drain, so as to cover the portion that acts as the channel. An organic conducting layer that acts as a gate is formed on the insulating layer so as to overlay the portion of the organic conducting layer that acts as the channel.

### BACKGROUND OF THE INVENTION

1. Field of the Invention

This invention relates to an organic field-effect transistor, an organic electronic device that represents the organic field-effect transistor and other devices in more general terms, and methods of manufacturing the organic field-effect transistor and organic electronic device.

2. Description of the Related Art

The development of electronic devices using organic materials has resulted in the new field of light-weight, flexible, inexpensive plastic electronics. Various organic electronic devices have been proposed. For example, see H. E. Katz and Z. Bao, “The Physical Chemistry of Organic Field-Effect Transistors”, J. Phys. Chem., 104, 671 (2000); C. J. Drury, C. M. Mutsaers, C. M. Hart, M. Matters and D. M. deLeeuw, “Low-cost all-polymer integrated circuits”, Appl. Phys. Lett., 73, 108 (1998); and H. Sirringhaus, N. Tessler and R. H. Friend, “Integrated Optoelectronic Devices Based on Conjugated Polymers”, Science, 280, 1741 (1998), etc.

In the organic electronic devices introduced in these references, an active layer (channel layer) is formed by an organic semiconductor material. The active layer consisting of the organic semiconductor material essentially contains no carriers and therefore a problem which arises is that the operating voltage is high (several tens of volts to 100 volts or more), meaning that the device is not suited to practical use.

Further, the organic electronic devices introduced in these references use, in part, inorganic semiconductor materials such as silicon, or employ organic semiconductor materials even in all-organic devices. With the former, conventional silicon semiconductor manufacturing processes must be employed in part and, as a consequence, the features of organic electronic devices and their methods of manufacture cannot be exploited fully. The latter involves a comparatively high operating voltage, as mentioned above.

### DISCLOSURE OF THE INVENTION

Accordingly, an object of the present invention is to provide an organic field-effect transistor or organic electronic device having a new structure that employs an organic conducting material.

A further object of the present invention is to provide an organic field-effect transistor or organic electronic device having a comparatively low operating voltage.

A still further object of the present invention is to provide an all-organic-type organic field-effect transistor or organic electronic device that employs an organic conducting material.

A still further object of the present invention is to provide a comparatively simple method of manufacturing the above-mentioned organic field-effect transistor or organic electronic device.

In principle the present invention may be expressed in its most theoretical form as follows: In a field-effect transistor in which a channel is provided between a source and drain each comprising a conductor and a gate to which is applied a voltage for controlling a current that flows into the channel is provided via an insulating layer disposed between the gate and at least the channel, the present invention is characterized in that at least the channel is composed of (formed by) an organic conducting material. It will suffice if the channel is provided in a form capable of forming a current path between the source and drain. The organic conducting material will be described later in greater detail. The source, drain and gate are formed of conductors in the broadest sense of the term and include organic conductors, metals and doped inorganic semiconductors, etc. Since the channel (comprises) is constituted by (formed of) an organic conducting material, the operating voltage can be reduced (on the order of several volts).

In this specification, the term “field effect” is used in its broadest sense to mean that a current which flows into a channel between a source and a drain (a current path between portions or regions corresponding to a source and a drain) is controlled by an electric field produced by a voltage applied to a gate (or to a portion or region corresponding to a gate) (where “control” includes the formation or extinction of a current path). Depending upon the case, the source, drain, channel and gate may be expressed as a source region or source portion, drain region or drain portion, channel region or channel portion and gate region and gate portion, respectively.

Described first will be a mode applicable to an all-organic-type organic field-effect transistor or organic electronic device.

One mode of an organic field-effect transistor (FET) according to the present invention has a source, a channel and a drain consisting of a single organic conducting material and being continuous within an organic conductor (first organic conductor); a conductor (second conductor) acting as a gate being provided on one surface of the organic conductor via an insulator; a region in which the conductor overlaps the organic conductor serving as a channel region; and one of the organic conductor and insulator or conductor being provided on a single substrate.

The organic FET may be expressed differently, namely as an organic FET comprising: an organic conductor (first organic conductor) in which a source region, a channel region and a drain region are connected seamlessly therein so as to form a current path from the source region to the drain region via the channel region; a conductor (second conductor) acting as a gate to which is applied a voltage that controls conductivity of the channel region of the organic conductor; an insulator provided between the organic conductor and the conductor; and a substrate for supporting one of the organic conductor and insulator or conductor; wherein the insulator is spread over an area that covers at least the channel region on one surface of the organic conductor, and the conductor resides in an area in which it overlaps the channel region and does not overlap the source region and the drain region.

Expressed more generally, the present invention provides an organic electronic device. The organic electronic device comprises: an organic conductor (first organic conductor) in which a first region, a second region and a third region are connected seamlessly therein so as to form a current path from the first region to the third region via the second region (channel); a conductor (second conductor) to which is applied a voltage that controls conductivity of the second region of the organic conductor; an insulator provided between the organic conductor and the conductor; and a substrate for supporting one of the organic conductor and insulator or conductor; wherein the insulator is spread over an area that covers at least the second region on one surface of the organic conductor, and the conductor resides in an area in which it overlaps the second region and does not overlap the first region and the third region.

Most generally, the organic conductor is obtained by doping an organic semiconductor with a dopant (a substance exhibiting an electron acceptor property or electronic donor property). Types of organic semiconductors include polythiophene, polypyrrole, polyaniline, polyacetylene, polyphenylene, polyfuran, polyselenophene, polyisothianaphthene, polyphenylene sulfide, polyphenylenevinylene, polythienylenevinylene, polynaphthalene, polyanthracene, polypyrene, polyazulene, phthalocyanine, pentacene, melocyanine and derivatives thereof. Dopants include iodine, perchloric acid, hydrochloric acid, sulfuric acid, nitric acid, phosphoric acid, boron tetrafluoride, arsenic pentafluoride, hexafluorophosphate, alkyl sulfonate, perfluoroalkyl sulfonate, polyacrylic acid and polystyrene sulfonate, etc. These organic semiconductors and dopants can be combined freely.

Examples of the organic conductor (first organic conductor) are an organic conducting layer and an organic conducting film.

The conductor (second organic conductor) may be an organic or inorganic material (a metal or a doped semiconductor, etc.) so long as the material is electrically conductive.

Similarly, the insulator may be an organic insulator or an inorganic insulator. It should be understood that the insulator includes an air layer.

The conductor (second conductor) and insulator also include those in the form of a film or layer.

The substrate may be formed from either an organic or inorganic material, and an insulator or conductor (or semiconductor) is used depending upon the form or type of the organic field-effect transistor or organic electronic device.

By way of example, the substrate is an insulator (or object having an insulating layer formed at least on the surface thereof) in a case where the organic conductor (first organic conductor) is supported on the substrate. Of course, an insulating layer may be formed on a conductive substrate and an organic conducting layer may be provided on the insulating layer. The organic conductor itself may be used as the substrate (i.e., the organic conductor may serve the dual purposes of an organic conductor and substrate) (this mode also is covered by a substrate supporting an organic conductor or by a limitation to the effect that an organic conductor is provided on a substrate).

The substrate may be a conductor or an insulator in a case where the conductor (second conductor) is supported on the substrate. Thus the conductor (second conductor) may serve the dual purposes of a conductor and substrate (This mode also covers an arrangement in which a substrate supports a conductor). An insulating layer may be formed on the conductive substrate and a conductor (second conductor) may be provided on the insulating layer.

Most generally, the organic conductor (first organic conductor), insulator and conductor (second conductor) are formed in layer or film form and are built up on the substrate.

In a case where the insulator is an organic insulator, the conductor (second conductor) is an organic conductor (second organic conductor) and the substrate is an organic substrate, the organic field-effect transistor or organic electronic device according to the present invention is implemented as an all-organic type.

The transistor or device is of the normally-on and normally-off type. In the normally-on type, a current flows into the channel (second region) of the organic conductor (first organic conductor) in a state in which voltage is not applied to the conductor (second conductor) (gate). In the normally-off type, the current does not flow in the above-mentioned state. In either case, the current (conductivity) that flows into the channel (second region) can be controlled by the voltage applied to the conductor. The organic field-effect transistor or organic electronic device according to the present invention acts as a switching element or amplifying element.

The above mode of the present invention is characterized in that the source (first region), channel (second region) and drain (third region) are connected seamlessly within the organic conductor (first organic conductor). The extent of the region of the channel (second region) is defined by the extent of the spread of the conductor (second conductor) provided via the insulator, and the regions connected to both sides of the region of the channel (second region) in the organic conductor are portions that act as the source (first region) and drain (third region). It will suffice if the source (third region) and drain (third region) have a width needed to effect an electrical (electronic) connection to other electronic or electrical circuits (inclusive of simple wiring and electrical connections).

Thus, according to the present invention, the source (first region), channel (second region) and drain (third region) can be formed seamlessly by a single organic conductor. As a result, the structure is simple and manufacture easy because the organic conductor, insulator and conductor are supported on a single substrate.

In one embodiment, the organic field-effect transistor or organic electronic device has a low operating voltage and exhibits a switching function (the ON/OFF ratio of which is 100 or greater) when a voltage applied to the conductor acting as the gate falls within the range of −5 V to 5 V or 0 to −5 V.

Typically, if special configurations are excluded, methods of manufacture are classified into two types. The first type is a method of building up an organic conducting layer, insulating layer and conducting layer on a substrate in the order mentioned. The second type is a method of building up a conducting layer, insulating layer and organic conducting layer on a substrate in the order mentioned.

The first manufacturing method is defined in concrete terms as follows: The first manufacturing method comprises the steps of: forming an organic conducting layer on a single substrate, at least the surface of which exhibits an insulating property, in such a manner that portions acting as a source, channel and drain are rendered continuous; forming an insulating layer on the organic conducting layer so as to cover at least the portion acting as the channel (excluding at least part of the portions acting as the source and drain); and forming a conducting layer acting as a gate on the insulating layer so as to overlap the portion of the organic conducting layer serving as the channel (so as not to overlap the portions serving as the source and drain).

It is possible to manufacture an organic field-effect transistor by implementing at least three patterning processes, namely patterning of an organic conducting layer, patterning of an insulating layer and patterning of a conducting layer.

If the first manufacturing method is expressed generally as a method of manufacturing an organic electronic device, the method comprises the steps of: forming an organic conducting layer on a single substrate, at least the surface of which exhibits an insulating property, in such a manner that portions acting as a first region, second region and third region are rendered continuous; forming an insulating layer on the organic conducting layer with the exception of at least part of the first region and third region; and forming a conducting layer on the insulating layer so as to overlap the second region of the organic conducting layer.

The second method of manufacturing an organic electronic device comprises the steps of: forming an insulating layer so as to cover at least a portion of a conducting layer on a single substrate having the conducting layer portion at least on the surface thereof; and forming a second region that overlaps the portion of the conducting layer covered by the insulating layer, as well as a first region and a third region connected to the second region on both sides thereof so as not to overlap the conducting layer and, moreover, in a state in which they are insulated from the substrate.

An organic FET according to another mode according to the present invention expressed in a more general form comprises: a source, a channel and a drain disposed so as to be capable of conducting electrically by forming a current path from a source (region) to a drain (region) via a channel (region), a least the channel being formed by an organic conducting material; and a gate provided via an insulator that covers at least the surface of the channel and to which is applied a voltage that controls the conductivity of the channel; the source, channel and drain, or the insulator or gate, being supported on the substrate.

Expressed more generally, an organic electronic device according to the present invention comprises: first, second and third regions disposed so as to be capable of conducting electrically, in such a manner that a current path is formed from the first region to the third region via the second region, a least the second region being formed by an organic conducting material; and a fourth region provided via an insulator that covers at least one surface of the second region and to which is applied a voltage that controls the conductivity of the second region; the first to third regions, or the insulator or fourth region, being supported on the substrate.

The source (first region), drain (third region) and gate (fourth region) are formed by an organic conductor, an inorganic conductor (a metal or a doped semiconductor) or other conducting material. In manner similar to that of the mode described above, the source (first region), channel (second region), drain (third region), gate (fourth region) and insulator generally are implemented in the form of a film or layer. Further, the substrate itself may constitute any one or a plurality of a source (first region), channel (second region) and drain (third region), and the substrate itself may constitute the insulator or gate (fourth region).

An organic FET or organic electronic device having the above structure also acts as a switching element or amplifying element. Since the channel (second region) is formed by an organic conducting material, the operating voltage thereof is comparatively low, thereby making practical use possible.

If the organic FET of the above mode according to the present invention is expressed more concretely, it may be expressed in the form of the following two embodiments:

Specifically, an organic FET of a first embodiment comprises: a source region and a drain region formed on a substrate at least the surface of which exhibits an insulating property, and a channel region formed on the substrate between the source and drain regions, at least the channel region being formed by an organic conducting material; an insulating layer formed so as to cover at least the channel region; and a gate region formed on the insulating layer in an area in which it overlaps at least the channel region.

An organic FET of a second embodiment comprises: an insulating layer formed on a substrate at least the surface of which has a conducting portion acting as a gate region; a source region and a drain region formed on the substrate in a state insulated from the substrate, or formed on the insulating layer; and a channel region formed on the insulating layer between the source region and the drain region; at least the channel region being formed by an organic conducting material.

Methods of manufacturing these organic FETs also can be classified broadly into two methods of manufacture.

A first manufacturing method comprises the steps of: forming a source region and a drain region on a substrate at least the surface of which exhibits an insulating property, and a channel region on the substrate between the source and drain regions, at least the channel region being formed by an organic conducting material; forming an insulating layer so as to cover at least the channel region; and forming a gate region on the insulating layer in an area in which it overlaps at least the channel region.

A second manufacturing method comprises the steps of: forming an insulating layer on a substrate at least the surface of which has a conducting portion acting as a gate region; and forming a source region and a drain region on the insulating layer and a channel region on the insulating layer between the source region and the drain region; at least the channel region being formed by an organic conducting material.

Since at least the channel region formed by an organic conducting material does not necessarily require the use of a conventional semiconductor manufacturing process, it is possible to simplify the manufacturing steps.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a plan view illustrating a partially broken-away view of an organic FET according to a first embodiment of the present invention;

FIG. 2 is a sectional view taken along line II-II in FIG. 1;

FIG. 3 is a graph illustrating a drain voltage vs. drain current characteristic of the organic FET;

FIG. 4 is a circuit diagram of a circuit for driving an organic FET and measuring its characteristics;

FIG. 5 is a graph illustrating the relationship between the gate voltage of the organic FET and the square root of drain current;

FIG. 6 is a graph illustrating a change in the ON/OFF ratio of the organic FET with a change in gate voltage;

FIG. 7 is another graph showing a drain voltage vs. drain current characteristic of the organic FET;

FIG. 8, which is a plan view illustrating a process for manufacturing the organic FET, shows the patterning of a mask for forming a first organic conducting layer;

FIG. 9, which is a plan view illustrating a process for manufacturing the organic FET, shows a phase of the process where the first organic conducting layer has been formed;

FIG. 10, which is a plan view illustrating a process for manufacturing the organic FET, shows the patterning of a mask for forming an insulating layer;

FIG. 11, which is a plan view illustrating a process for manufacturing the organic FET, shows the patterning of a mask for forming a second organic conducting layer;

FIG. 12 is a sectional view corresponding to FIG. 2 and illustrating another example of an organic FET;

FIG. 13 is a plan view illustrating a partially broken-away view of an organic FET according to a second embodiment of the present invention;

FIG. 14 is a sectional view taken along line XIV-XIV in FIG. 13;

FIG. 15 is a sectional view corresponding to FIG. 14 and illustrating a modification of the organic FET; and

FIG. 16 is a sectional view corresponding to FIG. 14 and illustrating another example of an organic FET.

### DESCRIPTION OF THE PREFERRED EMBODIMENTS

Preferred embodiments of the present invention will now be described in detail with reference to the drawings.

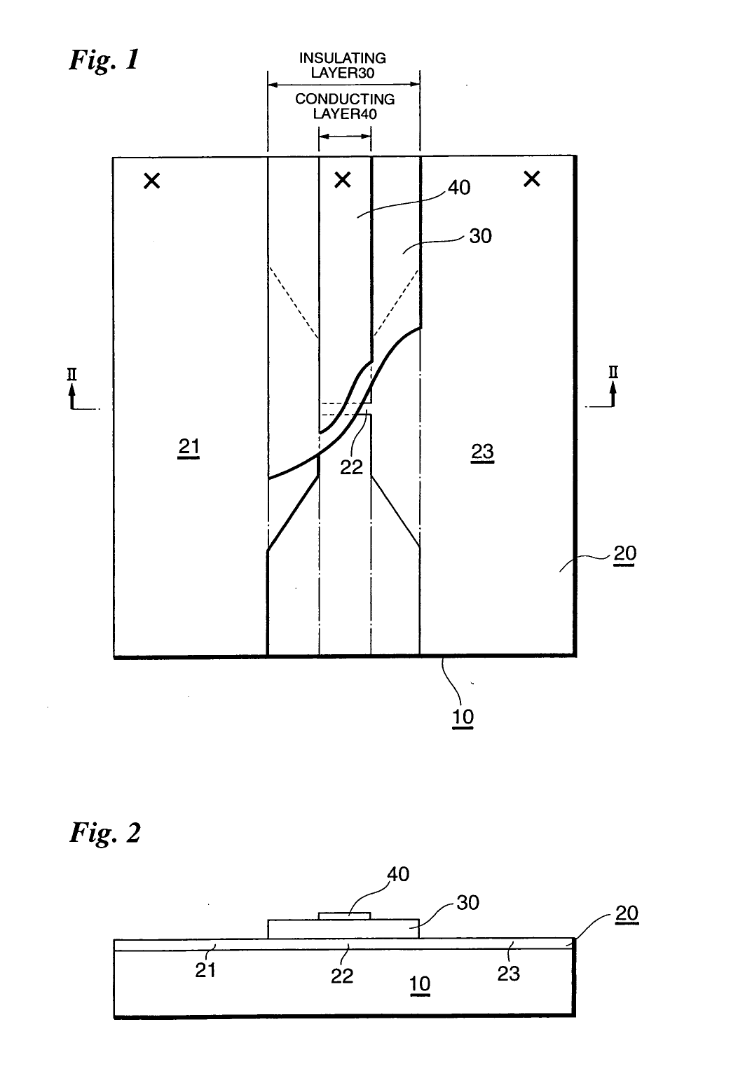

FIGS. 1 and 2 illustrate the structure of an organic field-effect transistor (referred to simply as an “organic FET” below) according to a first preferred embodiment of the present invention.

As shown in FIGS. 1 and 2, a first organic conducting layer 20 is formed on an organic substrate 10. The organic conducting layer 20 has a source (source region) 21, a drain (drain region) 23 and a slender channel (channel region) 22 between the source and drain. The source 21, channel 22 and drain 23 are connected seamlessly. (The lines indicating the boundaries of the regions 21, 22 and 23 do not appear in FIG. 2.) The source 21 and drain 23 are spaced away from each other except for the portion where they are interconnected by the channel 22.

An insulating layer 30 is formed on the organic conducting layer 20. In this embodiment, the insulating layer 30 is provided in the shape of a band that includes a zone covering the channel 22 and portions of the source 21 and drain 23 extending trapezoidally to the side of the channel 22. However, it will suffice if the insulating layer 30 covers the upper portion of at least the channel 22.

A second organic conducting layer 40 acting as a gate is formed on the insulating layer 30. The second organic conducting layer 40 is formed in the shape of long, slender band having a width that covers the entire length of the channel 22. Conversely, the area of the first organic conducting layer 20 overlapped by the second organic conducting layer 40 is the channel 22.

The source 21 and drain 23 of the first organic conducting layer 20, and the second organic conducting layer 40, are used as terminals for effecting a connection to a power supply and other electrical or electronic circuits, etc. The connection to the power supply and other electrical or electronic circuits is achieved by a conductive adhesive, integration or simply by clips, etc.

In the drawings, the first organic conducting layer 20 is formed up to the edges of the substrate 10. However, it goes without saying that the first organic conducting layer 20 need not be formed on part of the substrate 10 or on the edges thereof. Further, though the insulating layer 30 and second organic conducting layer 40 also are formed in the shape of a band extending from one edge of the substrate 10 to the opposite edge thereof, these need not reach the edges.

Specifically, the organic FET is such that the substrate 10 is PET [poly(ethylene terephthalate)] film having a thickness of 100 μm, the first organic conducting layer 20 is poly(3,4-ethylene dioxythiophene) doped with poly(4-styrenesulfonate) (referred to below as “PEDOT/PSS”) having a thickness of 25 to 40 nm, the insulating layer 30 is poly(4-vinylphenol) (referred to as “PVP” below) having a thickness of 400 nm, and the second organic conducting layer 40 is PEDOT/PSS having a thickness of 200 to 500 nm. The width and length of the channel 22 are 0.23 mm and 1.03 mm, respectively.

The organic FET according to this embodiment is an all-organic FET in which the substrate 10, first organic conducting layer 20, insulating layer 30 and second organic conducting layer 40 all consist of organic material.

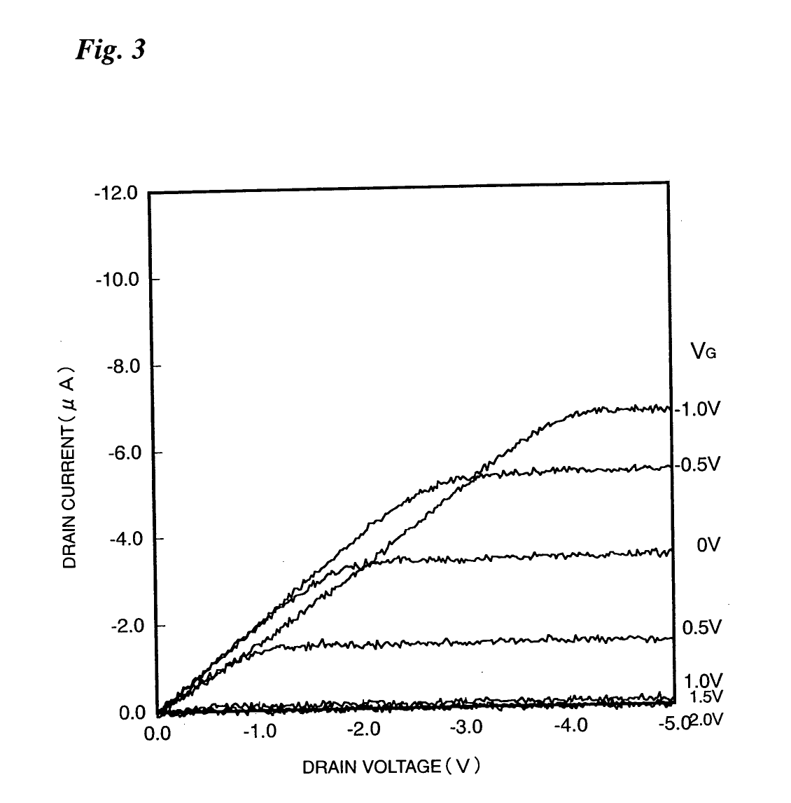

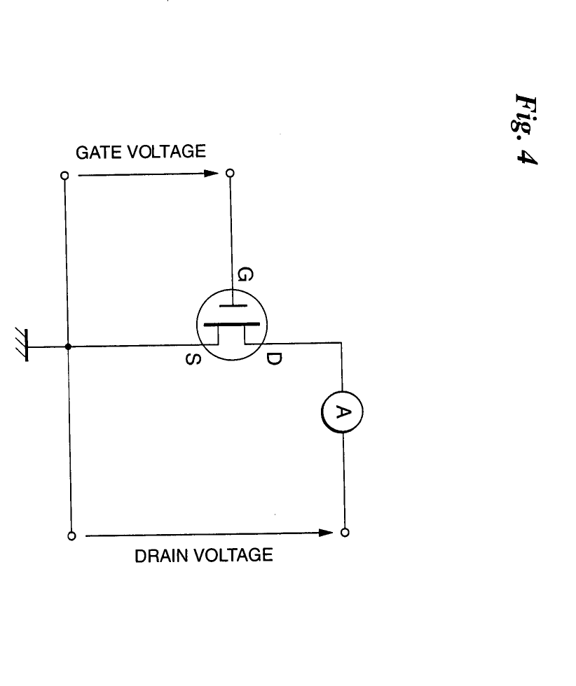

FIG. 3 is a graph illustrating a drain voltage vs. drain current characteristic of the above-described organic FET. This characteristic was measured by the circuit arrangement shown in FIG. 4. Specifically, a source (S) is grounded and voltages are applied to a drain (D) and gate (G) using the source as a reference. (These voltages are a drain voltage and a gate voltage V_{G}.) A current that flows into the drain (D) is a drain current. In the measurement, the measurement circuit was connected using the positions indicated by the “×” symbols as terminals in the structure of the organic FET depicted in FIG. 1.

In a case where a gate voltage (gate-source voltage) is not applied (V_{G}=0 V), the drain current in the graph of FIG. 3 increases substantially linearly with an increase in the drain voltage (an increase in the negative direction). A conducting channel is formed as the channel 22 of the first organic conducting layer 20. This organic FET is of the normally-on type.

When the gate voltage is raised in the positive direction, the drain current decreases. It is believed that this is due to holes within the conductive channel 22 recombining with electrons induced by the gate voltage (electric field). When the gate voltage exceeds 1.5 V, drain current no longer flows. That is, the organic FET assumes the OFF state. The organic FET exhibits a depression-type response when the gate voltage is in the positive range.

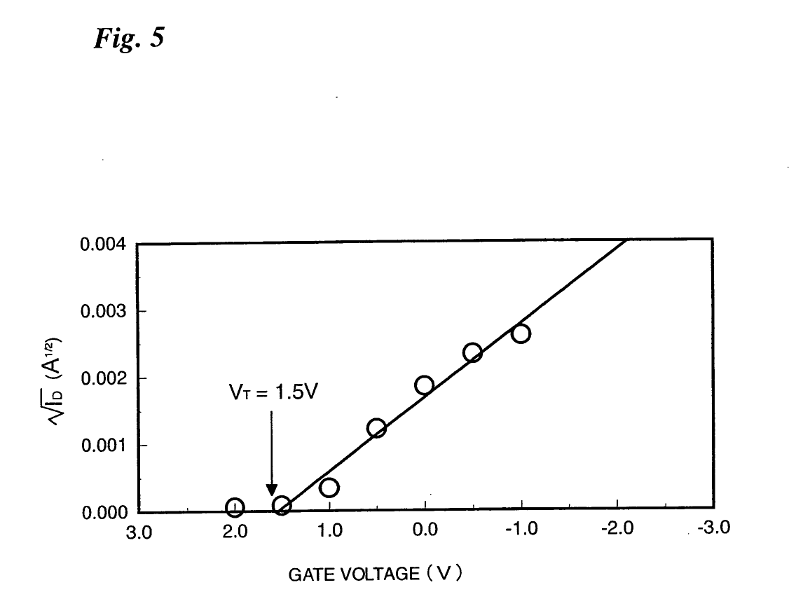

As shown in FIG. 5, which is a plot of the value of the square root of drain current I_{D} versus gate voltage V_{G}, the drain current I_{D} is zero when the gate voltage V_{G} is 1.5 V. The threshold value (voltage) is 1.5 V.

Conversely, if the gate voltage is increased in the negative direction, the drain current increases and the organic FET exhibits an enhancement-type response. It is believed that this is due to holes induced within the channel 22.

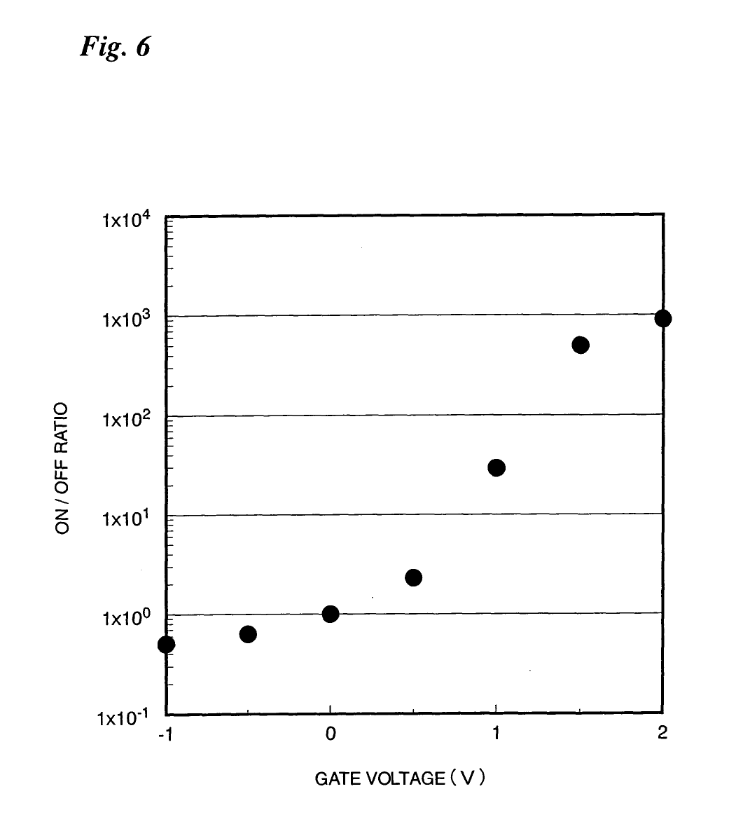

FIG. 6 illustrates the result of measuring the ON/OFF ratio, which is the ratio of the drain current in the ON state to the drain current in the OFF state. It will be understood that the ON/OFF ratio attains a value of 1000 when the gate voltage is 2 V, so that the switching function is fully achieved.

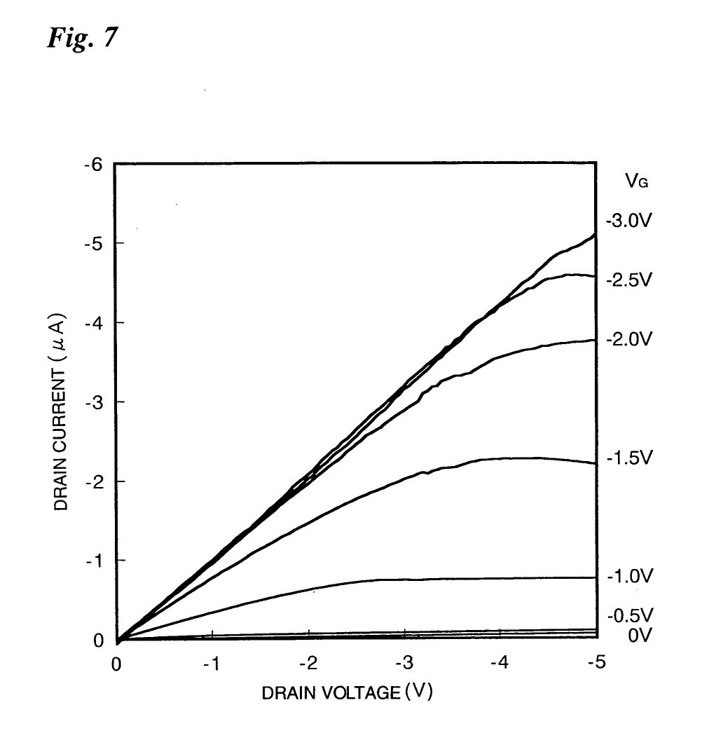

The graph of FIG. 7 illustrates a drain voltage vs. drain current characteristic of the organic FET of FIGS. 1 and 2 in a case where an aluminum electrode has been formed on the entire surface of the upper side of gate 40. Almost no drain current flows in a case where no gate voltage is applied (V_{G}=0). If the gate voltage is enlarged in the negative direction, the drain current increases and the organic FET exhibits only an enhancement-type response.

The difference between the characteristic shown in FIG. 7 and that depicted in FIG. 3 can be explained as follows: When the gate (G) is grounded in the circuit diagram of FIG. 4 (V_{G}=0), a potential difference is produced between the drain and gate if a negative voltage is being applied to the drain (D). A depletion layer is formed in the channel 22 by this potential difference and no current flows between the source (S) 21 and drain (D) 23. This is the reason why the characteristic shown in FIG. 7 is obtained.

The terminal of gate 40 is situated at the end of the slender gate 40, as indicated by the “×” symbol in FIG. 1. The resistance of the insulating layer 30 is not infinitely large and only a minute leakage current flows through the insulating layer 30. The distance between the position of the “×” symbol of gate 40 and the position immediately above the channel 22 is comparatively long and a voltage drop occurs owing to flow of leakage current across this distance. That is, even though the gate voltage is 0 V (even though the position of the “×” symbol of gate 40 is connected to ground), a negative voltage is actually produced at the position directly above the channel 22 owing to the voltage drop ascribable to the leakage current [in a case where a negative voltage is applied to the drain (D)]. Accordingly, in comparison with the case where the aluminum electrode is formed on the upper surface of the gate 40 (in this case, almost no voltage drop ascribable to leakage current occurs), it is believed that the potential difference between the drain and gate declines and that the depletion layer formed in the channel 22 is reduced. At gate voltage V_{G}=0, therefore, a current (drain current) flows between the source and drain and the characteristic shown in FIG. 3 is obtained.

By utilizing the phenomenon described above, either an organic FET that exhibits only an enhancement-type response or an organic FET that exhibits both an enhancement-type response and a depletion-type response can be realized as desired by changing the structure of the device or the arrangement of the external circuitry.

Carrier mobility and conductivity of a channel will be discussed next.

According to the prior art, e.g., the above-mentioned paper by H. E. Katz and Z. Bao, it has been reported that field-effect mobility and conductivity, which are obtained in a case where an organic semiconductor (pentacene, polythiophene, phthalocyanine, etc.) is used as the channel, are on the order of 10⁰ to 10⁻⁸ cm²/Vs and 10⁰ to 10⁻⁸ S/cm, respectively.

By contrast, with a channel that employs an organic conductor (PEDOT/PSS cited above), a field-effect mobility of several tens of cm²/Vs or greater and a conductivity of several S/cm or greater are obtained.

Thus, when an organic conductor is used, it is possible to realize an organic FET having a high mobility and conductivity.

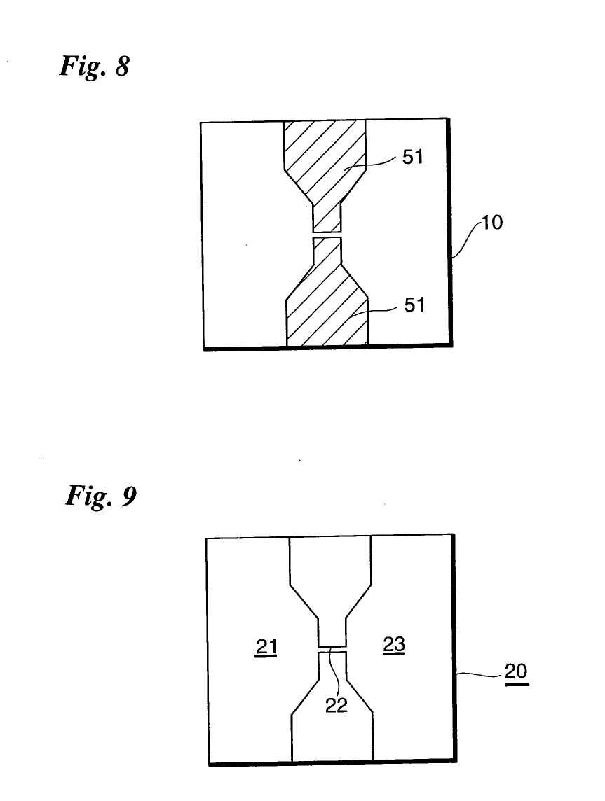

FIGS. 8 to 10 illustrate a process for manufacturing the organic FET described above.

As shown in FIG. 8, a mask 51 is patterned on the PET film substrate 10 in an area thereof that excludes a region in which the first organic conducting layer 20 is to be formed. Though various well-known patterning methods can be used, the simplest method is to print the mask 51 using a laser printer.

Next, the substrate 10 is coated with a PEDOT/PSS solution. Bar coating is satisfactory as the coating method.

This is followed by removing the mask 51, whereby the first organic conducting layer 20 having the patterns of the regions for the source 21, channel 22 and drain 23 is formed on the substrate 10, as illustrated in FIG. 9. The toner of the laser printer is removed by ultrasonic cleaning in toluene.

As shown in FIG. 10, a mask 52 is patterned on the first organic conducting layer 20 with the exception of the area in which the insulating layer 30 is to be formed, then a coating of PVP is applied from an isopropanol solution. The mask 52 is then removed.

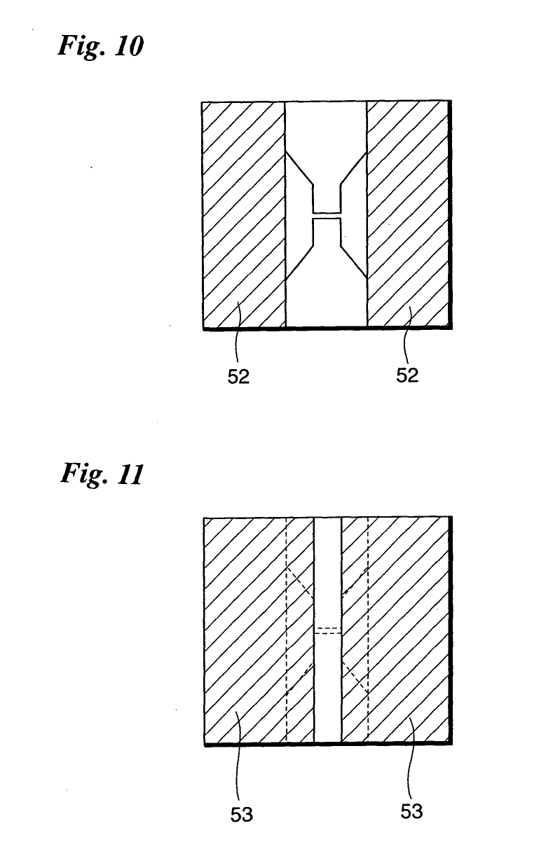

Finally, as shown in FIG. 11, a mask 53 is formed except in the area in which the second organic conducting layer 40 is to be formed, then a coating of PEDOT/PSS solution is applied. The mask 53 is then removed.

The masks 52, 53 (and mask 51 as well) can also be patterned using a conventional method such as photolithography or vacuum deposition, or patterning may be achieved simply by placing or affixing patterning paper or patterning tape. The coating can be implemented by spin coating or spray coating, etc., in addition to the above-mentioned bar coating.

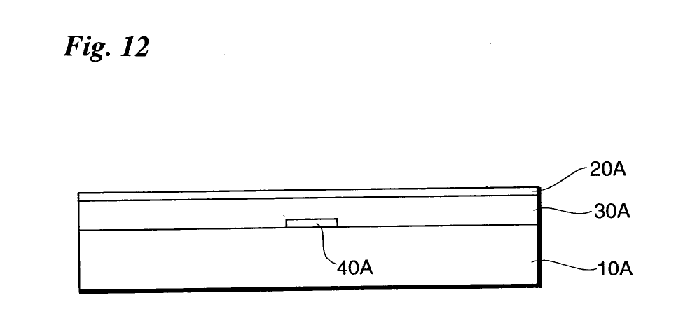

FIG. 12 illustrates another example of the structure of an organic FET according to the present invention. Here a second organic conducting layer 40A acting as a gate is formed on an insulating substrate 10A, and an organic insulating layer 30A is formed on the insulating substrate 10A and the second organic conducting layer 40A with the exception of a portion of the second organic conducting layer 40A that is to serve as a connection terminal. A first organic conducting layer 20A is formed on the organic insulating layer 30A. The first organic conducting layer 20A has a source and drain formed in areas where they will not overlap the second organic conducting layer 40A, and a channel formed in an area where it will overlap the second organic conducting layer 40A. Alternatibely, an insulating layer may be formed on an electrically conductive substrate, and the second organic conducting layer 40A may be formed on this insulating layer. The first organic conducting layer 20A is held in a state in which it is insulated from the substrate by the above-mentioned insulating layer or the organic insulating layer 30A.

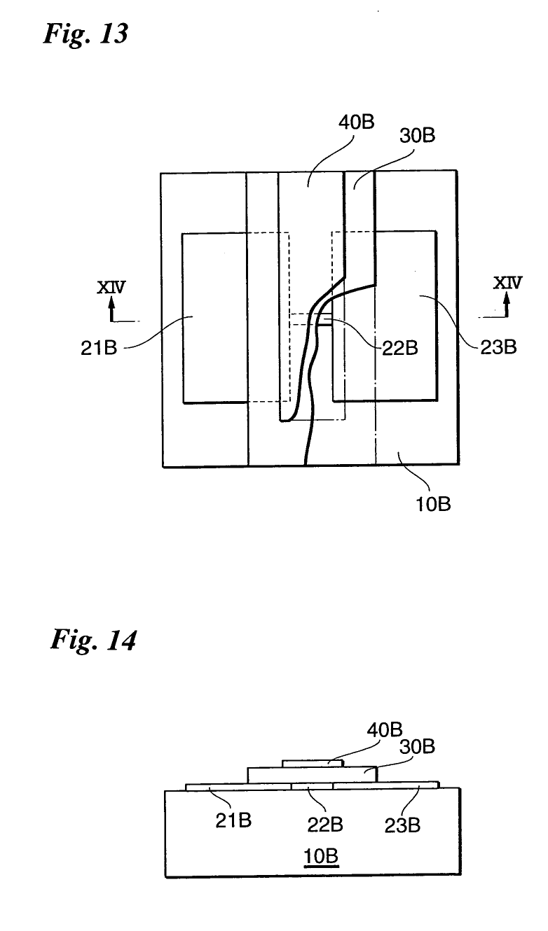

FIGS. 13 and 14 illustrate the structure of an organic FET according to a second embodiment of the present invention. Here a metal film is vapor-depoisted on a glass substrate (insulating substrate) 10B by photolithography, and a source (source region) 21B and drain (drain region) 23B are formed. A gap corresponding to the length of a channel 22B to be formed exists between the source 21B and drain 23B. The slender channel (channel region) 22B is formed by spin coating of an organic conducting material (PEDOT/PSS cited above) using a mask with the exception of the portion where the channel is to be formed. The channel 22B contacts the source 21B and drain 23B so that a state in which these are capable of conducting electrically is achieved.

An insulating layer 30B is formed as by spin coating (with use of a mask as a matter of course) so as to cover at least the channel 22B. The insulating layer 30 may be formed so as to cover the source 21B and drain 23B with the exception of the portions that are to serve as their terminals. A gate (gate region) 40B is formed on the insulating layer 30B by photolithography and by vapor deposition of metal so as to overlap at least the channel 22B.

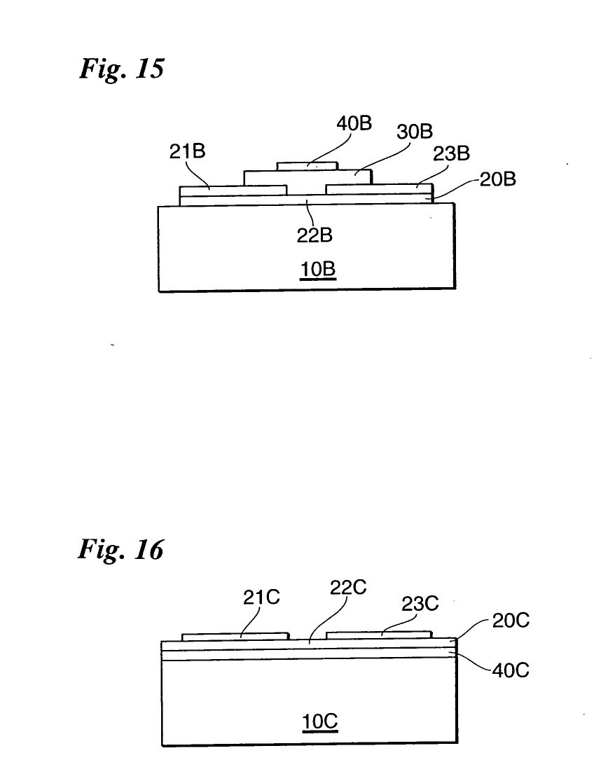

The organic FET of the second embodiment is such that only the portion that is the channel 22B is formed by an organic conducting material. As shown in FIG. 15, an arrangement may be adopted in which an organic conducting layer 20B of the kind depicted in FIG. 9 is formed on the glass substrate 10B and a metal that is to serve as the source (the electrode or terminal thereof) 21B and as the drain (the electrode or terminal thereof) 23B is formed on the organic conducting layer 20B on the portions thereof on both sides of the portion that is to serve as the channel 22B. Other structural aspects are the same as those shown in FIG. 14.

FIG. 16 illustrates a modification, which is of the bottom-gate type. Here an SiO₂ insulating layer 40C is formed on a silicon substrate (one doped with a dopant and exhibiting conductivity) 10C. An organic conducting film (PEDOT/PSS) 20C is formed on the insulating layer 40C in a shape that encompasses a slender channel 22C of the kind depicted in FIG. 9. A source (the electrode or terminal thereof) 21C and a drain (the electrode or terminal thereof) 23C are formed by metal on the organic conducting film 20C on the portions (source and drain regions) thereof contiguous to both sides of the channel 22C. The silicon substrate 10C acts as a gate. Gate terminals are formed on the silicon substrate 10C.

As many apparently widely different embodiments of the present invention can be made without departing from the spirit and scope thereof, it is to be understood that the invention is not limited to the specific embodiments thereof except as defined in the appended claims.

What is claimed is:

1. An organic field-effect transistor having a source, a channel and a drain consisting of a single organic conducting material, said source, channel and drain being continuous within an organic conductor;
wherein a conductor acting as a gate is provided on one surface of said organic conductor via an insulator, and a region of said organic conductor in which said conductor overlaps said organic conductor serves as a channel region;
one of said organic conductor and said insulator or said conductor being provided on a single substrate.

2. The organic field-effect transistor according to claim 1, wherein said conductor is an organic conductor and said insulator is an organic insulator.

3. The organic field-effect transistor according to claim 1, wherein said organic conductor is an organic conducting layer, said insulator is an insulating layer, and said conductor is a conducting layer;
said organic conducting layer, said insulating layer and said conducting layer being built up on a single substrate.

4. The organic field-effect transistor according to claim 1, wherein said substrate is formed from an organic material.

5. The organic field-effect transistor according to claim 1, wherein said transistor has a switching function when a gate voltage applied to said conductor falls within a range of −5 V to 5 V or 0 to −5 V.

6. An organic field-effect transistor comprising:
an organic conductor in which a source region, a channel region and a drain region are connected seamlessly therein so as to form a current path from the source region to the drain region via the channel region;
a conductor acting as a gate to which is applied a voltage that controls conductivity of said channel region of said organic conductor;
an insulator provided between said organic conductor and said conductor; and
a substrate for supporting one of said organic conductor and said insulator or said conductor;
wherein said insulator is spread over an area that covers at least said channel region on one surface of said organic conductor, and said conductor resides in an area in which it overlaps said channel region and does not overlap said source region and said drain region.

7. An organic electronic device, comprising:
an organic conductor in which a first region, a second region and a third region are connected seamlessly therein so as to form a current path from the first region to the third region via the second region;
a conductor to which is applied a voltage that controls conductivity of said second region of said organic conductor;
an insulator provided between said organic conductor and said conductor; and
a substrate for supporting one of said organic conductor and said insulator or said conductor;
wherein said insulator is spread over an area that covers at least said second region on one surface of said organic conductor, and said conductor resides in an area in which it overlaps said second region and does not overlap said first region and said third region.

8. A method of manufacturing an organic field-effect transistor comprising the steps of:
forming an organic conducting layer on a single substrate, at least the surface of which exhibits an insulating property, in such a manner that portions of said layer acting as a source, channel and drain are rendered continuous;
forming an insulating layer on said organic conducting layer with the exception of at least part of the portions acting as the source and drain; and
forming a conducting layer acting as a gate on said insulating layer so as to overlap the portion of said organic conducting layer serving as said channel.

9. A method of manufacturing an organic electronic device comprising the steps of:
forming an organic conducting layer on a single substrate, at least the surface of which exhibits an insulating property, in such a manner that portions of said layer acting as a first region, second region and third region are rendered continuous;
forming an insulating layer on said organic conducting layer with the exception of at least part of the first region and third region; and
forming a conducting layer on said insulating layer so as to overlap said second region of said organic conducting layer.

10. A method of manufacturing an organic electronic device comprising the steps of:
forming an insulating layer so as to cover at least a portion of a conducting layer on a single substrate having the conducting layer portion at least on the surface thereof; and
forming a second region that overlaps the portion of said conducting layer covered by said insulating layer, as well as a first region and a third region connected to said second region on both sides thereof so as not to overlap said conducting layer and, moreover, in a state in which they are insulated from said substrate.

11. An organic field-effect transistor comprising:
a source, a channel and a drain disposed so as to be capable of conducting electrically by forming a current path from a source to a drain via a channel, at least the channel being formed by an organic conducting material; and
a gate provided via an insulator that covers at least the surface of said channel and to which is applied a voltage that controls the conductivity of said channel;
said source, channel and drain, or said insulator or said gate, being supported on the substrate.

12. The organic field-effect transistor according to claim 11, wherein said transistor has a switching function when a gate voltage applied to said gate falls within a range of 0 to −5 V.

13. An organic electronic device comprising:
first, second and third regions disposed so as to be capable of conducting electrically, in such a manner that a current path is formed from said first region to said third region via said second region, at least said second region being formed by an organic conducting material; and
a fourth region provided via an insulator that covers at least one surface of said second region and to which is applied a voltage that controls the conductivity of said second region;
said first to third regions, or the insulator or said fourth region, being supported on the substrate.

14. A field-effect transistor comprising:
a source region and a drain region formed on a substrate at least the surface of which exhibits an insulating property, and a channel region formed on the substrate between the source and drain regions, at least said channel region being formed by an organic conducting material;
an insulating layer formed so as to cover at least said channel region; and
a gate region formed on the insulating layer in an area in which it overlaps at least said channel region.

15. A field-effect transistor comprising:
an insulating layer formed on a substrate at least the surface of which has a conducting portion acting as a gate region;
a source region and a drain region formed on the substrate in a state insulated from the substrate, or formed on said insulating layer; and
a channel region formed on said insulating layer between said source region and said drain region;
at least said channel region being formed by an organic conducting material.

16. A method of manufacturing an organic field-effect transistor, comprising the steps of:
forming a source region and a drain region on a substrate at least the surface of which exhibits an insulating property, and a channel region on the substrate between the source and drain regions, at least the channel region being formed by an organic conducting material;
forming an insulating layer so as to cover at least the channel region; and
forming a gate region on the insulating layer in an area in which it overlaps at least the channel region.

17. A method of manufacturing an organic field-effect transistor, comprising the steps of:
forming an insulating layer on a substrate at least the surface of which has a conducting portion acting as a gate region; and
forming a source region and a drain region on the insulating layer and a channel region on the insulating layer between the source region and the drain region;
at least the channel region being formed by an organic conducting material.

18. An organic field-effect transistor comprising:
a source and a drain each consisting of a conductor;
a channel provided between said source and said drain; and
a gate, to which a voltage for controlling a current that flows into said channel is applied, provided via an insulating layer disposed between said gate and at least said channel;
at least said channel being composed of an organic conducting material.
